(19) United States
(12) Patent Application Publication
(10) Pub. No.: US 2013/0169345 A1
(43) Pub. Date: Jul. 4, 2013

(54) ELECTRONIC RELAY, ELECTRONIC SYSTEM AND METHOD FOR SWITCHING A POWER CURRENT

(71) Applicant: Michael Bauer, Rosengarten Westheim (DE)

(72) Inventor: Michael Bauer, Rosengarten Westheim (DE)

(73) Assignee: WURTH ELEKTRONIK ICS GMBH & CO. KG, Ohringen (DE)

(21) Appl. No.: 13/512,559

(22) PCT Filed: Nov. 26, 2010
(86) PCT No.: PCT/EP10/68329

§ 371 Date: Mar. 19, 2013

(30) Foreign Application Priority Data
Nov. 26, 2009 (DE) 10 2009 047 171.5

(51) Int. Cl. H03K 17/00

(52) U.S. Cl. CPC H03K 17/00
USPC 327/419

(57) ABSTRACT

The invention relates to an electronic relay with
an input plug-in contact (30) and at least one output plug-in contact (87, 87a) for a current to be switched,
an electronic component (104) for processing data and for actuating a semiconductor switch (116) for switching the current,
a wireless communications interface (106, 108) for connection to a wireless communications network (150), wherein the wireless communications interface is embodied for receiving a first switching signal (120),
a control plug-in contact (15) for receiving a second switching signal (122),
at least one signal input plug-in contact (W, X, Y, Z) for receiving at least a first data signal (152),
   wherein the electronic component is embodied such that the semiconductor switch is actuated for switching the current based upon the reception of the first or second switching signal, and such that the first data signal received via at least one signal input plug-in contact is processed and, based upon a result of the data processing of the first data signal, the semiconductor switch is actuated for switching the current.

The invention relates to an electronic relay, an electronic system comprising at least one electronic relay and a method for switching a power current by means of an electronic relay.

Electronic relays are known in the prior art. Electronic relays are also referred to as semiconductor relays or solid state relays (SSR). An electronic relay comprises a controllable semiconductor switch, for example, a transistor, thyristor or triac, for the purpose of switching a power current.

From U.S. Pat. No. 6,360,277 B1 an SSR is known, which has a supplemental optical control input for an infrared channel. A standard can be used for the infrared control, such as is known from the field of consumer electronics.

In contrast, the problem addressed by the invention is that of devising an improved electronic relay, an electronic system and a method for switching a power current.

Each of the problems addressed by the invention is solved by the features of the independent patent claims. Embodiments of the invention are specified in the dependent claims.

According to embodiments of the invention, an electronic relay with plug-in contacts, i.e., a so-called plug-in relay, is provided. The electronic relay can be embodied such that it can be plugged or pressed into a socket arranged on a printed circuit board, or into the printed circuit board directly. The electronic relay has at least one input plug-in contact and one output plug-in contact for a current to be switched, along with one control plug-in contact. The electronic relay further has an electronic component, for example, an integrated logic circuit, particularly one or more processors, for example, for executing program instructions and for actuating a semiconductor switch for switching a power current by means of the input plug-in contact and the output plug-in contact.

The electronic relay has further a wireless communications interface for connection to a wireless communications network, wherein the wireless communications interface is embodied for receiving a first switching signal. The control plug-in contact, in contrast, is used for receiving a second switching signal.

The electronic component is embodied in a way that the semiconductor switch is actuated for switching the current based upon the reception of the first or the second switching signal.

The electronic relay has further at least one input plug-in signal for receiving at least the first data signal. The first sensor signal can act as an indicated value, especially as sensor signal of a printed circuit (PC) board.

When the electronic component receives the first data signal via at least one signal input sensor plug-in, said signal is processed, for example, by executing the program instructions, and the semiconductor switch is actuated or is not actuated for switching the current based upon a result of the processing of the first data signal. The data processing implemented by the electronic component can be fully or partially realized by means of a hard-wired logic circuit.

The semiconductor switch can be a transistor, particularly a field-effect transistor, for example, a MOSFET, or some other semiconductor switch, for example, a thyristor or a triac. More particularly, the semiconductor switch can be embodied as a so-called “high side switch”, i.e. as a MOSFET which switches the “high side” or positive side of the power current.

For example, the electronic relay is embodied for switching a power current that is used to supply power to one or more electrical units or drives.

The wireless communications interface of the electronic relay serves to establish a connection with a wireless communications network, which operates at a radio frequency. The wireless communications network can be implemented as a WLAN network or as a wireless personal area network (WPAN). As a WPAN, the wireless communications network can be implemented by means of Bluetooth, ultra-wideband (UWB), Z-wave or ZigBee, for example. More particularly, the wireless communications network can comply with the standard IEEE 802.15.4.

In particular, the wireless communications network can be a wireless ad-hoc network, for example, a wireless ad-hoc network (MANET), a wireless mesh network (WMN), a wireless sensor network (WSN) and/or a vehicular ad-hoc network (VANET).

Embodiments of the invention are particularly advantageous because the electronic relay can be actuated alternatively on-wire or wirelessly. In other words, the first and/or second switching signal for switching the power current can be received via the wireless communications interface of the electronic relay or via the control plug-in contact, wherein the control plug-in contact is connected to a printed circuit board, for example, via which the switching signal can be transmitted. For transmission of the switching signal via the printed circuit board, the circuit board can have a wired data bus, for example, a field bus, CAN or LIN bus, or an RS232 interface, particularly if the electronic relay is an addressable electronic relay.

Via at least one signal input plug-in, the electronic relay can receive at least a first data signal. The first data signal can, for example, be a measured value from a sensor or a threshold value, which is processed by executing the program instructions. The switching of the current by means of the electronic relay when the first or the second switching signal is received can be dependent on the measured value and/or the threshold value, for example.

According to the embodiments of the invention, an electronic relay is provided, which enables an expanded range of functions as a result of its wireless communications interface, and thereby ensures downward compatibility with customary electronic plug-in relays. More particularly, embodiments of the invention enable the implementation of an expanded range of functions in an existing design of an electronic system at minimal expense. Embodiments of the invention further enable the creation of client-specific variants of such an electronic system due to the flexibility provided by the wireless communications network, which enables the addition of further electronic relays or other components with or without connection to the printed circuit board, for example.

It is particularly advantageous that a plug-in relay according to the invention can be implemented as a customary standardized plug-in relay both with respect to its exterior form and with respect to the configuration of its plug-in contacts. A plug-in relay according to the invention can thus have a standardized housing shape and/or standardized plug-in contact, which can be connected by customary techniques to a printed circuit board or a printed circuit board socket, more particularly by plugging in or pressing in.

According to one embodiment of the invention, the first data signal is a measured value. The measured value is processed by means of the program instructions of the electronic relay, in which a check is carried out to determine whether the measured value satisfies a predefined criterion for actuating the semiconductor switch for switching the current. The predefined criterion can be a threshold value, for example. If the measured value received with the first data signal by the electronic relay exceeds such a threshold value, for example, then the predefined criterion is satisfied, and the electronic component will actuate the semiconductor switch for switching the current. An additional prerequisite for switching the current can be that the first and/or the second switching signal are received.

According to one embodiment of the invention, the first data signal contains a specification of the predefined criterion, i.e., for example, the threshold value. This threshold value is stored by the electronic component. When an additional first data signal with a measured value is subsequently received, a check of this measured value is carried out by executing the program instructions, to determine whether said value exceeds the previously received threshold value, so as to actuate the semiconductor switch on this basis.

According to one embodiment of the invention, the electronic component is embodied such that, by executing the program instructions, a second data signal is generated, wherein the wireless communications interface is embodied for transmitting the second data signal.

For example, the second data signal is generated as a result of the processing of the first data signal by executing the program instructions. More particularly, the second data signal can be a switching signal, which is transmitted by the electronic relay via the wireless communications interface to another electronic relay of the wireless communications network. One result of the processing of the first data signal by means of the electronic relay, for example, can be that not only this electronic relay, but also another electronic relay of the wireless communications network must switch, so that the second data signal with the switching signal directed toward this additional electronic relay will be generated and transmitted via the wireless communications interface.

According to one embodiment of the invention, the second data signal is transmitted as a unicast, multicast or broadcast signal, i.e., the data signal is addressed to a single subscriber (unicast), to a group of subscribers (multicast) or to all subscribers of the wireless communications network (broadcast).

According to one embodiment of the invention, the data processing results in the detection of the fulfillment of an emergency shut-off condition. As a result of the detection of the fulfillment of an emergency shut-off condition, a second data signal is generated, which contains a shut-off command, wherein the second data signal is transmitted as a broadcast signal. Thus, if it is established as a result of the processing of the first data signal by the electronic component that an emergency shut-off condition has been fulfilled, the second data signal with the shut-off command will be transmitted as a broadcast signal to all subscribers, causing them to switch off the relevant currents. The emergency shut-off condition can involve the detection of a fire or a hazardous operating state, for example.

The electronic component can assign the emergency shut-off condition a threshold value, with which a sensor value of the first data signal is compared, in order to check whether the emergency shut-off condition has been fulfilled. Rather than a comparison, more complex data processing may be necessary, in which additional data or switching signals can be included, in addition to the first data signal.

According to one embodiment of the invention, the measured values and/or the status of the inputs/outputs are made available without local processing to one, several, or all subscribers of the wireless communications network, in that corresponding signals are transmitted by the electronic relay, e.g., via its wireless communications interface. In this manner, the realization, for example, of a pure sensor function of the electronic relay is possible.

Via the wireless communications interface, the electronic relay apart from the first switching signal can receive a third data signal. The third data signal can be for example a measured value of a sensor or threshold, which can be fabricated by implementing the program instructions. As an example, when the first or second switching signal will be received, the current switch through the electronic relay can be dependent from the measured value or threshhold. The third data signal can be included, for example, in the processing of the first data signal and/or in the generation of the second data signal.

For example, the electronic relay can receive an updated threshold value with the first data signal, and subsequently a measured value with the third data signal. By executing the program instructions, the measured value is then compared with the updated threshold value in order to switch the current, for example, if the measured value lies above the threshold value. In this case, the reception of the first and/or second switching signal can be a supplemental condition for actuation of the semiconductor switch for switching the current. Moreover, the program instructions can be embodied such that additional criteria must be satisfied in order to actuate the semiconductor switch for switching the current, for example, the reception of additional sensor signals, which must in turn also satisfy predefined criteria, so that when all the predefined criteria are satisfied, the semiconductor switch is actuated for switching the current.

According to one embodiment of the invention, the electronic relay comprises a logic circuit, for example, a first microcontroller with an integrated wireless communications interface, which contains a processor and peripheral components, for example, inputs/outputs, a memory, and a communications interface, and also comprises a second, additional, higher capacity microcontroller for executing at least part of the program instructions. As a result of the microcontroller and the increased computing capacity that it provides, correspondingly complex functions and test criteria can be implemented by means of the electronic component.

According to one embodiment of the invention, the electronic relay is equipped with a bus interface for connection with an internal and/or an external wired data bus, for example, a field bus, particularly a profibus, or a CAN or LIN bus or an RS232 interface.

According to one embodiment of the invention, the electronic relay has a self-diagnosis component for detecting an error status. The self-diagnosis component can be embodied as a so-called watchdog circuit, which performs continuous checks to determine whether one or more predefined errors have occurred. When an error status has been detected by the self-diagnosis component, a corresponding error status signal is generated, which is transmitted by the electronic relay via the wireless communications interface, for example, to the so-called coordinator of the wireless communications network. The coordinator can temporarily remove the relevant electronic relay from the network on the basis of the error status.

For example, the self-diagnosis component can reinitialize the electronic relay following detection of the error status, for example, by restarting the execution of the program instructions. Once the error situation has been corrected and an error status no longer exists, the self-diagnosis component can generate another signal, which is transmitted to the coordinator of the wireless communications network, whereupon the relevant relay is added back to the wireless communications network, for example, by so-called ad-hoc association.

According to one embodiment of the invention, the electronic relay is embodied for performing the function of a coordinator, router, or end device in the wireless communications network, particularly according to the ZigBee standard.

In a further aspect, the invention relates to an electronic system with a printed circuit board, into which one or more electronic relays according to the invention are plugged.

The electronic system can be a so-called powerboard, for example. With a powerboard, lines are provided on the printed circuit board both for signal transmission and for the transmission of power currents, and can be configured using bus bar technology. The powerboard can have plugged-in or pressed-in power electronics elements along with wired or SMD components.

According to a further embodiment of the invention, the electronic system can be a central electrical system, particularly for vehicles, for example, for motor vehicles or ships.

According to one embodiment of the invention, the printed circuit board supports a coordinator for the wireless communications network, wherein the coordinator can be an electronic relay according to the invention.

According to one embodiment of the invention, the electronic system comprises at least one component which is separate from the printed circuit board, and which can be movable relative to the printed circuit board. Communication with this component that is separate from the printed circuit board is carried out via the wireless communications network.

The electronic system can comprise at least two printed circuit boards, for example, which can be arranged spatially separately from one another and without galvanic connection, for example, in different parts of a vehicle.

According to one embodiment of the electronic system, the system is modular in design. For example, in a basic embodiment the electronic system can have a single printed circuit board and in another embodiment can have an additional second printed circuit board, resulting in an expanded range of functions.

According to one embodiment of the invention, the wireless communications interface of the electronic relay is embodied for receiving an update of the program instructions, for example, from a coordinator of the wireless communications network. This enables the loading of program updates for correcting errors and/or expanding or modifying functions.

In a further aspect, the invention relates to a method for switching a power current, comprising the following steps:

Receiving the first switching signal via the wireless communications interface of the first electronic relay, whereupon the semiconductor switch of the first electronic relay is actuated for switching the power current; receiving the second switching signal via the control plug-in contact of the first electronic relay, whereupon the power current is actuated by actuating the semiconductor switch of the first electronic relay; receiving the first data signal via at least one input signal plug-in of the first electronic relay; and processing the first data signal by executing the program instructions of the first electronic relay, in order, based upon the result of the processing of the first data signal, to actuate the semiconductor switch of the first electronic relay for switching the power current and/or to generate the second data signal in order to transmit the second data signal via the wireless communications interface of the first electronic relay to a second electronic relay, wherein the second data signal received by the second electronic relay is processed in the same manner as the first data signal is processed by the first electronic relay. It can also be transmitted to selected additional subscribers (3, 4, . . . ) or to all subscribers of the network (broadcast).

A switching of the power current can therefore occur as a result of the reception of the first switching signal or the second switching signal, wherein in each case the satisfaction of additional criteria can be a prerequisite for switching the power current. Such a criterion can be that the first data signal is received, and that the result of the processing thereof by execution of the program instructions satisfies a specific criterion.

In addition or as an alternative to the switching of the power current, a second data signal is generated for transmission to another electronic relay of the electronic system. For example, the second data signal can comprise a switching signal for the additional electronic relay if, as a result of the processing of the first data signal, for example, not only the relevant electronic relay but also an additional electronic relay must be switched, for example. Selected additional subscribers (3, 4, . . . ) or all subscribers of the network can also be caused to switch (broadcast).

However, the second data signal can also contain different information, for example, a threshold value for the switching of the additional electronic relay.

The information received by the additional electronic relay based upon the second data signal is processed there by executing the program instructions, which can result in a further second data signal, which is then forwarded by the additional electronic relay via the wireless interface. The received second data signal is processed by the additional electronic relay, wherein the program instructions for the additional electronic relay can be the same as or different from those for the first electronic relay. In this manner, an electronic system with partitioned intelligence can be realized.

In a further aspect, the invention relates to an electronic system having a portable wireless remote controller and at least one first and one second electronic relay, wherein each of the electronic relays has an input plug-in contact and at least one output plug-in contact for a current to be switched, an electronic component for processing data and for actuating a semiconductor switch for switching the current, a wireless communications interface for connection with a wireless communications network, wherein the wireless communications interface is embodied at least for receiving a first switching signal, and a control plug-in contact for receiving a second switching signal, wherein the electronic component is embodied such that the semiconductor switch is actuated for switching the current on the basis of the reception of the first or second switching signal, and in that the first data signal received via the signal input plug-in is processed, and the semiconductor switch is actuated for switching the current based upon a result of the data processing of the first data signal, and/or the first data signal is forwarded to the respective other relay via the wireless communications network, wherein the wireless remote controller is embodied for transmitting the first switching signal via the wireless communications network.

In a further aspect, the invention relates to an electronic relay comprising registration means for registering the electronic relay in the wireless communications network, wherein the registration means are embodied for executing a registration protocol when the electronic relay is in a registration mode, and comprising switching means for switching the electronic relay to the registration mode, wherein the switching means comprise at least one contactless sensor, which is embodied for sensing an actuation operation by means of which the switching is initiated.

Embodiments of the invention are particularly advantageous because switching to the registration mode as a result of the sensing of an actuation operation can be carried out particularly simply, conveniently, securely and without wear and tear. It is particularly advantageous that the electronic relay can be completely encapsulated, with requiring a mechanical switch or the like to be actuated externally, which is particularly advantageous for protecting the electronic relay against environmental influences, for example, the effects of weather, dust and/or mechanical loads.

The registration protocol involves a pairing protocol, for example, such as is defined by the ZigBee standard, for example, see particularly the ZigBee RF4CE specifications. In this case, an embodiment of an electronic relay according to the invention can be added to a ZigBee network by switching the relevant electronic relay to the registration mode, wherein switching is implemented based upon a sensed actuation operation by a user.

According to one embodiment of the invention, the switching means for switching to the registration mode comprise one or more contactless magnetic field sensors, particularly one or more reed switches. A reed switch in this case is understood as any switch that is switched based upon an external magnetic field produced by a permanent magnet, for example, in other words it either opens or closes its switching contacts. If several such reed switches are arranged distributed in the electronic relay, then when a permanent magnet moves past them, for example, during the course of the actuation operation, a characteristic switching sequence results. This characteristic switching sequence is detected by the switching means, whereupon the system is switched to the registration mode. For example, the user holding a permanent magnet in his hand can carry out an actuation operation by moving the permanent magnet past the electronic relay in a certain manner, for example, by executing a certain gesture while holding the permanent magnet. This gesture results in a characteristic switching sequence of the reed switches, which then results in a switch to the registration mode.

Alternatively or in addition to magnetic sensors, one or more capacitive sensors can be arranged in the relay, wherein the one or more capacitive sensors are embodied for detecting a gesture executed by the user. The detection of this gesture by the switching means then in turn results in the switch to the registration mode.

According to a further embodiment of the invention, a pulse-width modulation of the power current is carried out by a corresponding actuation of the semiconductor switch. The pulse-width modulation that is necessary for adjusting to a specific current intensity is achieved by a corresponding first or second switching signal or by a corresponding first data signal, which result in an actuation of the semiconductor switch in order to thereby adjust the pulse-width modulation. This is particularly advantageous, because in this manner a separate component for adjusting current intensity can be dispensed with.

In what follows, embodiments of the invention will be specified in greater detail in reference to the set of drawings. The drawings show:

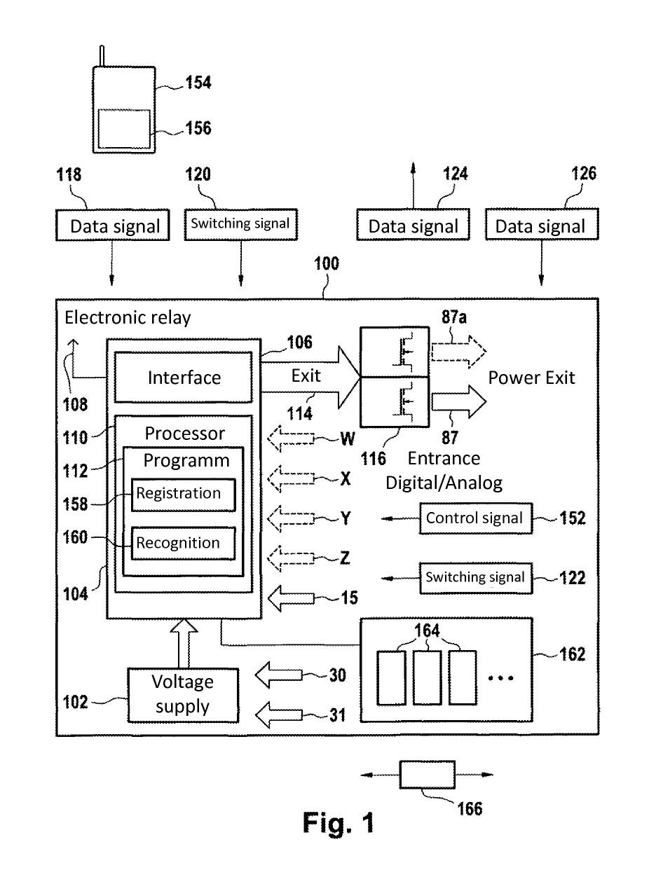

FIG. 1 a block diagram of a first embodiment of an electronic relay according to the invention,

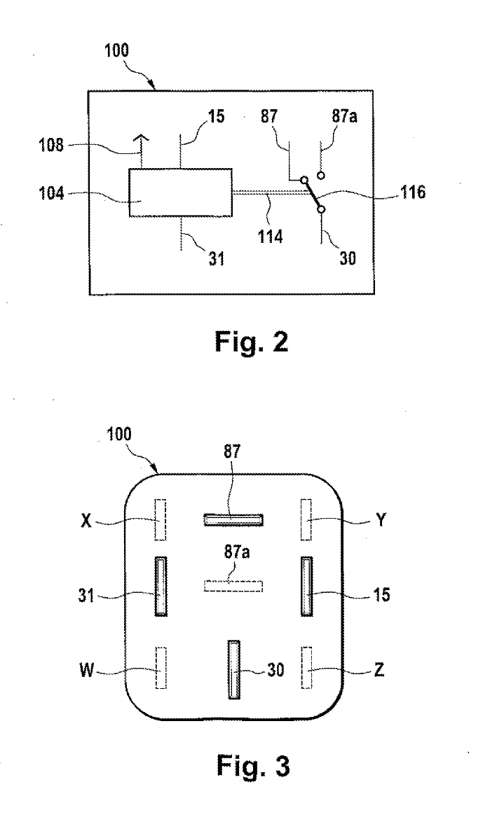

FIG. 2 a circuit analogy for the electronic relay according to FIG. 1,

FIG. 3 the plug-in contacts of the electronic relay of FIG. 1,

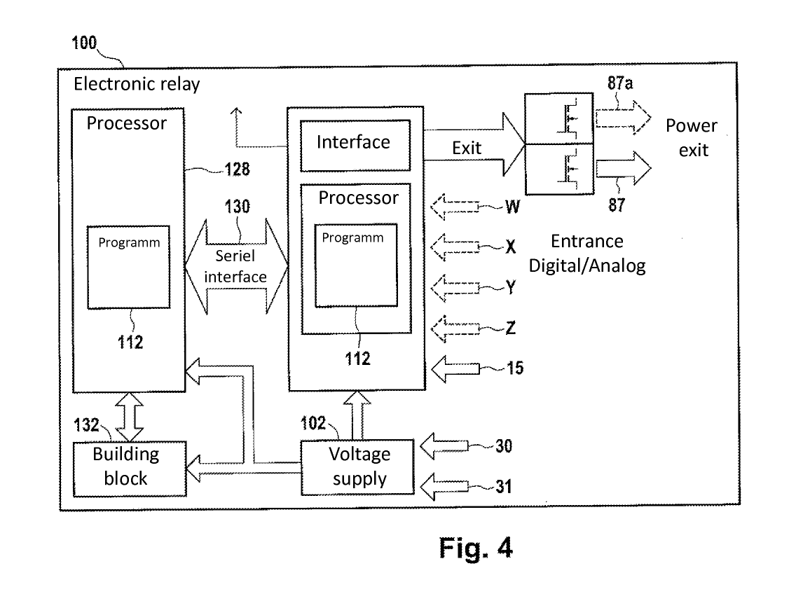

FIG. 4 a block diagram of a further embodiment of a relay according to the invention,

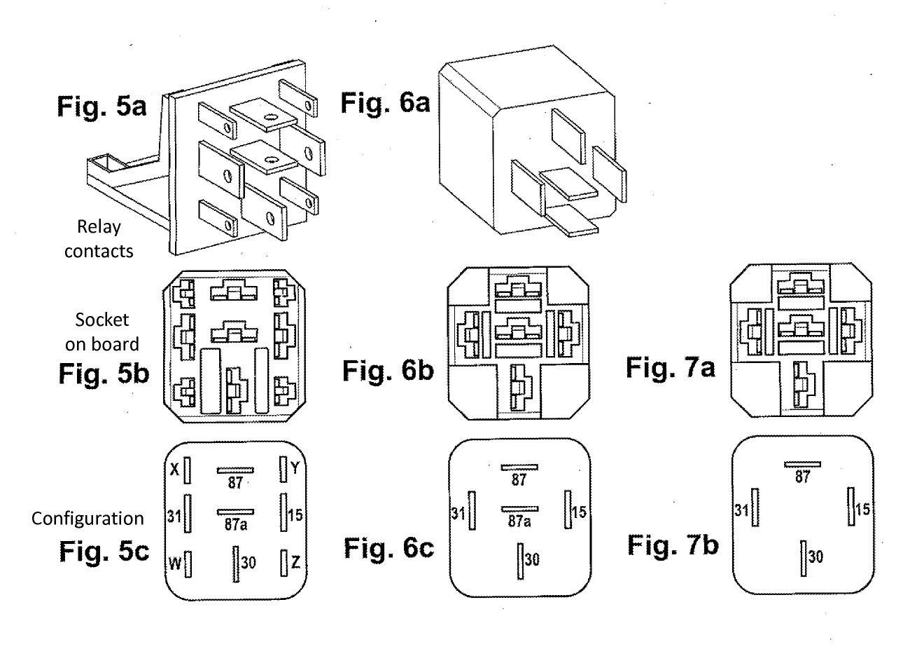

FIGS. 5a-c the plug-in contacts, the corresponding sockets and/or the assignment of the plug-in contacts of a nine-pole electronic relay according to the invention,

FIGS. 6a-c the plug-in contacts, the corresponding sockets, and/or the assignment of the plug-in contacts of a five-pole electronic relay according to the invention,

FIGS. 7a-b the sockets and/or the assignment of the plug-in contacts of a four-pole electronic relay according to the invention,

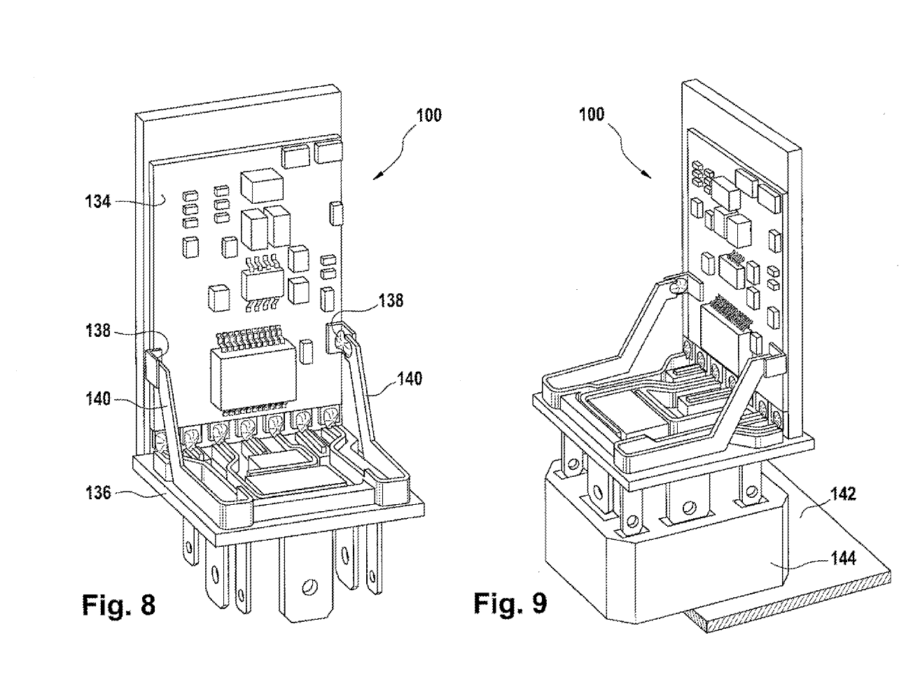

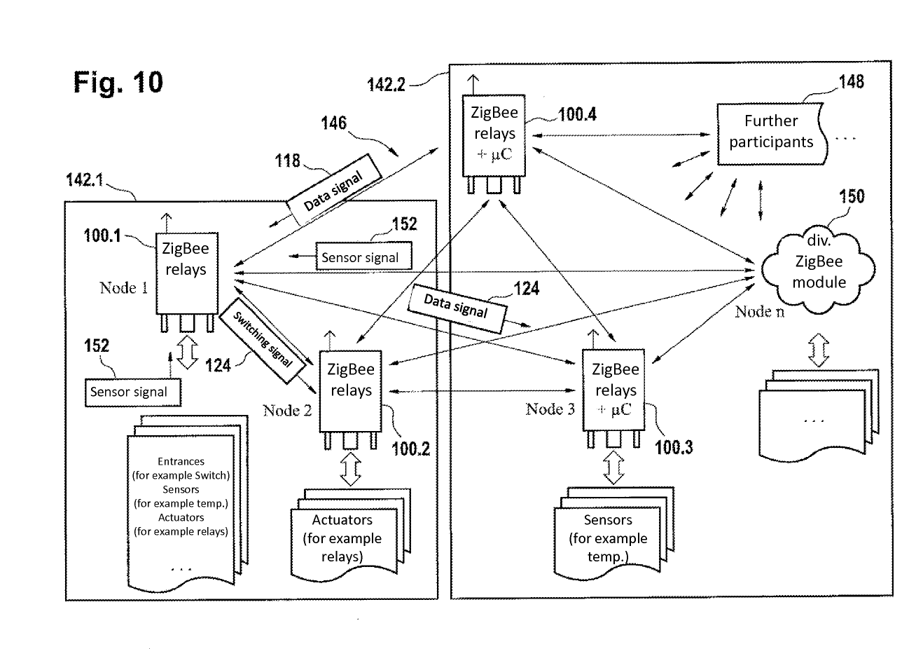

FIG. 8 one embodiment of an electronic relay according to the invention, in which the housing has been removed,

FIG. 9 the electronic relay of FIG. 8, which has been plugged into a socket,

FIG. 10 one embodiment of an electronic system according to the invention,

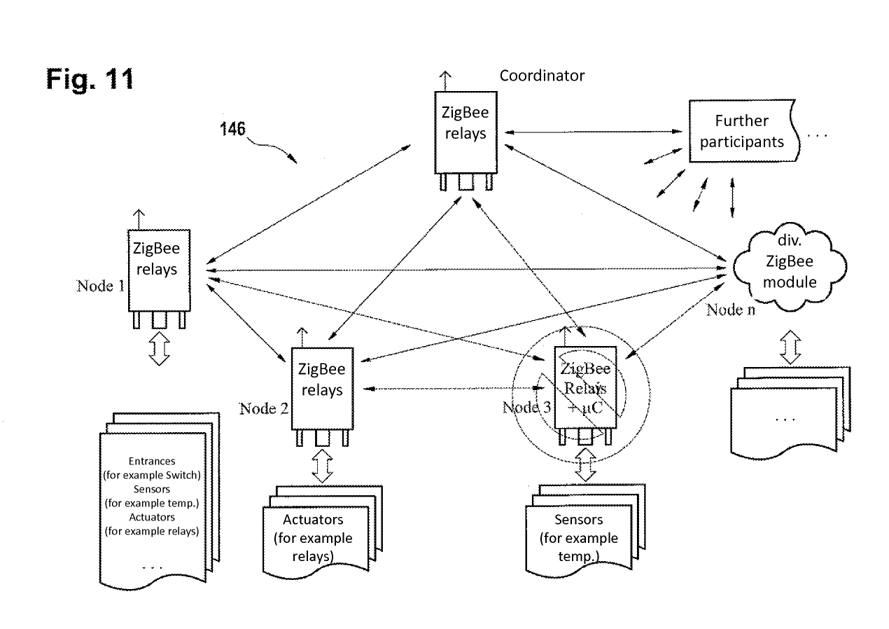

FIG. 11 the electronic system of FIG. 10 following the failure of one of the electronic relays,

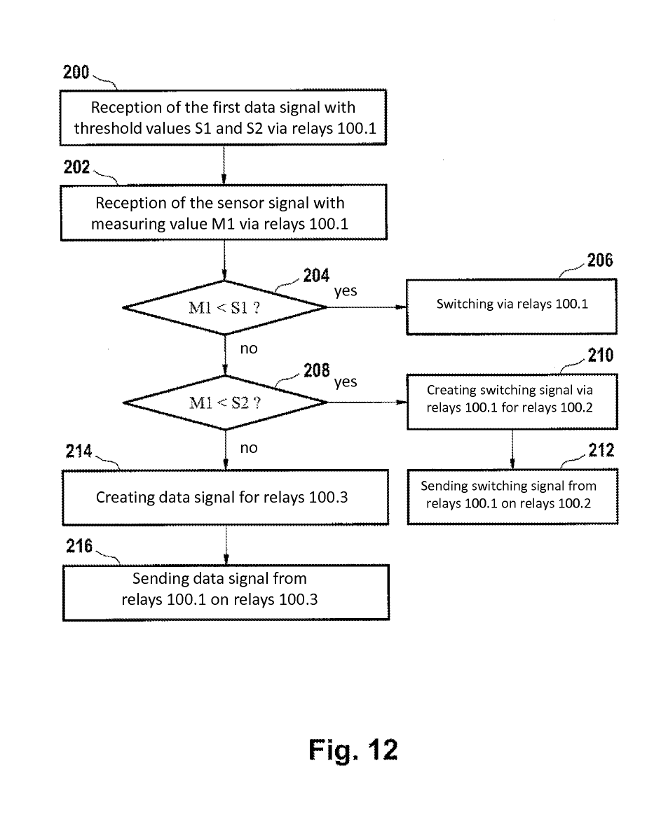

FIG. 12 a flow chart of one embodiment of a method according to the invention.

In the following description of the figures, corresponding elements of the different embodiments are identified in each case using the same reference signs.

FIG. 1 shows an electronic relay 100 with an input plug-in contact 30 for a current to be switched and at least one output plug-in contact 87 for the output current. Optionally, an additional output plug-in contact 87a can be provided if the electronic relay 100 is embodied as a combination of opener and closer, i.e. as a so-called changeover contact or transfer contact.

According to one embodiment of the invention, an opener or a closer is not involved, and instead, the two outputs 87 and 87a can be switched separately from one another.

The electronic relay 100 has a voltage supply circuit 102, which is connected to the input plug-in contact 30 and a grounding plug-in contact 31. Via the input plug-in contact 30 the voltage supply circuit 102 is supplied with electrical energy for operation of the electronic relay 100, so that the voltage supply circuit 102 can generate the operating voltage necessary for the operation of the electronic component 104 of the electronic relay 100. Alternatively or additionally, the electronic relay 100 can have a battery for providing the operating voltage.

The electronic component 104 comprises a wireless communications interface 106 with an antenna 108, which is embodied, for example, for connection with a wireless communications network 150 (cf. FIGS. 10 and 11) according to a so-called wireless personal area network (WPAN) standard, such as a ZigBee network, for example.

The electronic component 104 further comprises a processor 110 for executing program instructions 112. The processor 110 is part of a first microcontroller. The first microcontroller can also contain the wireless communications interface (e.g. for ZigBee). Otherwise, the first microcontroller has a decreased range of functions and/or a lower performance capacity as compared with a second microcontroller 128 (cf. FIG. 4).

The electronic component 104 is connected at least to a control plug-in contact 15 and to one or multiple additional signal input plug-in contacts, like for example signal input plug-in contacts W, X, Y and Z. The signal input plug-in contacts W, X, Y and Z can be embodied as digital or analog inputs. In this case, logical interconnections between the plug-in contact 15 and the signal input plug-in contacts W, X, Y, Z are possible for establishing one or multiple conditions that must be satisfied in order for the outputs 87 and/or 87a to switch. For example, only when X=1 and Y=1 will output 87 be switched. These logical interconnections can be realized by means of a dedicated logic circuit and/or by means of program logic.

The electronic component 104 has one or more outputs 114 for actuating one or more semiconductor switches 116 via which the current is to be switched. The semiconductor switch or switches 116 are connected to the output plug-in contact 87 or 87a.

For example the electronic relay 104 can receive the first data signal 152 via the signal plug-in contact Y, wherein it can act with data signal 152 for example with sensor signal of the sensor, which is connected with the signal contact plug-in Y for example through a data bus or directly. In embodiment through further signal input plug-in contacts the electronic relay 104 can receive further such first data signals from different sensors.

For example a sensor is locked on each of the signal input plug-in contacts, wherein each from the sensors delivers a first data signal from time to time, which is an advantage of a particularly short latent time regarding transfer and further processing of the first data signal. Besides, in this case, the sensors need no bus interface.

Via the wireless communications interface 106, the electronic relay 104 can receive further a first switching signal 120 and a third data signal 118. The electronic relay 100 can also receive a second switching signal 122 via the control plug-in contact 15.

The switching signals 120 and 122 and at least the first data signal 152 are processed by the processor 110 by executing the program instructions 112. The result of the processing can be that the electronic component 104 actuates the semiconductor switch or switches 116 via the outputs 114, in order to switch the current and/or to generate a second data signal 124, which carries information containing a result of the processing of the input signals, i.e., the data signal 152, the switching signal 120 and/or the switching signal 122, by means of the program instructions 112. The data signal 124 is transmitted via the wireless communications interface 106, for example, to another electronic relay according to the invention or to another subscriber 148 (cf. FIGS. 10 and 11) of the wireless communications network 150.

According to one embodiment of the invention, the electronic component 104 is embodied such that, based upon the reception of the switching signal 120 or 122, in each case the outputs 114 for switching the current are actuated, without requiring that additional criteria be satisfied for this purpose. According to one embodiment of the invention, the execution of the program instructions 112 for processing the data signal 152 and, based upon the result of this processing, for actuating the outputs 114 for switching the current is initiated based solely upon the reception of the data signal 152. The data signal 152 can be a measured value, for example, from a sensor, for example, such as a frequency value, a temperature value, a speed value, a pressure value, or the like, for example. A check of this measured value is then carried out to determine whether it satisfies a predefined criterion, for example, whether it exceeds a threshold value, so that—if this is the case—the outputs 114 for switching the semiconductor switch 116 will be actuated.

According to one embodiment of the invention, an additional prerequisite for switching the current can be that the switching signal 120 or 122 is also received.

According to one embodiment of the invention, the electronic relay 100, with its wireless communications interface 106, can receive another third data signal 126, which specifies one or more criteria that must be satisfied for the electronic component 104 to actuate the semiconductor switch 116, via the outputs 114, for switching the current. In this case, said signal can involve the threshold value, for example, which must be exceeded by the measured value of the data signal 152, in order for the electronic relay 100 to switch.

According to one embodiment of the invention, by executing the program instructions 112, the data signal 124 is generated and transmitted via the wireless communications interface 106 once the electronic relay 100 has received the data signal 152. One result of the analysis of the measured value of the data signal 152 can be, for example, that not only the electronic relay 100, but also an additional electronic relay, must switch in order for a corresponding data signal 124, which represents a switching signal, to be generated and transmitted to the relevant additional electronic relay. Multiple electronic relays or all the electronic relays of the network (broadcast) can also be switched—depending upon the programming and/or combinations of logical interconnections with the plug-in contact 15 and the signal input plug-in contacts W, X, Y, Z.

According to one embodiment of the invention, the switching signal 120 can be transmitted by a wireless remote controller 154, for example, which operates according to the ZigBee standard, for example. The wireless remote controller 154 has an operating field 156 for inputting data and/or a command by a user, for example, via a keyboard. Based upon a user input, the wireless remote controller 154 generates the switching signal 120, which is received by the electronic relay 100. Such a wireless remote controller 154 can also be used in an electronic system according to the invention, for example, according to the embodiments of FIG. 10 and FIG. 11, in order to generate a switching signal, for example, the switching signal 120, which is received by the wireless communications interface 106 of at least one of the electronic relays of the electronic system, depending upon whether the switching signal is a unicast, a multicast or a broadcast message.

According to one embodiment of the invention, the processor 110 serves for executing a program module 158 and a program module 160, which can be implemented through the program instructions 112. The program module 158 serves to implement a registration protocol for registering the electronic relay 100 in the wireless communications network, see wireless communications network 150 of FIG. 10. The registration protocol can be a so-called pairing protocol, particularly a ZigBee pairing protocol, for example, as is specified in ZigBee RF4CE of the ZigBee Alliance, www.zigbee.org.

The program module 160 serves for switching the electronic relay 100 to the registration mode, in which the registration protocol is executed. For switching to the registration mode, the electronic relay 100 has one or more contactless sensors 162. These can be embodied, for example, as capacitive proximity sensors or as inductive proximity sensors. Preferably, the sensors are embodied as multiple reed switches 164, which are arranged spatially distributed in the electronic relay.

When a user holds a permanent magnet 166 in his hand and moves it past the reed switches 164, this results in a corresponding switching sequence of the reed switches 164, which is received by the program module 160 in the form of a corresponding signal, and is compared with a predefined pattern. If the switching sequence is sufficiently consistent with the predefined pattern, the program module 160 will initiate the execution of the program module 158, to bring the electronic relay 100 to the registration mode, in which the registration protocol is executed.

For example, the user must execute a predefined gesture with the permanent magnet 166, for example, moving the permanent magnet once past the reed switches 164 from left to right, from right to left and then once again from left to right, in order to generate a switching sequence that is consistent with the predefined pattern. Alternatively, the sensors 162 can also be embodied for other forms of a contactless “gesture recognition” for recognizing an actuation operation by a user.

According to one embodiment of the invention, the power current can be pulse-width modulated via the semiconductor switch 116, in order to adjust to a desired current intensity. This can be carried out in such a way that a plurality of sequential data signals 118 switch the semiconductor switch 116 such that a pulse-width modulation having the desired resulting current intensity, which the user can input, for example, via the operating field 156 of the wireless remote controller 154, results. Rather than via the data signal 118, the pulse-width modulation can also be generated, for example, via a plurality of successive data signals 126, switching signals 120, switching signals 122 or control signals 152.

FIG. 2 shows a circuit analogy for the electronic relay 100 of the embodiment according to FIG. 1.

FIG. 3 shows the arrangement of the plug-in contacts of the electronic relay 100, i.e. of the control plug-in contact 15, the input plug-in contact 30, the grounding plug-in contact 31, the output plug-in contact 87 and the optional plug-in contact, i.e. the output plug-in contact 87a and the signal input plug-in contacts W, X, Y and Z. These plug-in contacts of the electronic relay 100 are embodied for plugging into a socket or for plugging or pressing or soldering directly into a printed circuit board. However, the contacts can also be connected by means of cables and cable terminals.

FIG. 4 shows a further embodiment of an electronic relay 100 according to the invention. In contrast to the embodiment according to FIG. 1, the electronic relay 100 in the embodiment of FIG. 4 has an additional processor, for example, of a second microcontroller 128, which serves for executing at least a part 112 of the program instructions, which can have a greater range of functions than the embodiment of FIG. 1 as a result of the computing capacity provided by the Microcontroller 128. Communication between the microcontroller 128 and the processor 110 can be carried out via a serial interface 130.

The electronic relay 100 can have additional building blocks, for example, a building block 132. Building block 132, for example, can be an interface for an external data bus of the printed circuit board, for example, a field bus, CAN bus or LIN bus, or RS232. The microcontroller 128 can then be coupled to the external data bus via the building block 132, for example. The building block 132 and the microcontroller 128 are supplied with power via the voltage supply circuit 102.

Alternatively or additionally, a self-diagnosis component, for example, a so-called watchdog, can be implemented by the building block 132.

FIG. 5 shows the relay contacts (FIG. 5a), a corresponding circuit board socket for a printed circuit board (FIG. 5b), and the signal assignment of the relay contacts (FIG. 5c) of a nine-pole embodiment of a relay according to the invention. FIG. 6 shows the relay contacts (FIG. 6a), a corresponding circuit board socket for a printed circuit board (FIG. 6b) and the signal assignment of the relay contacts (FIG. 6c) of a five-pole embodiment of a relay according to the invention. FIG. 7 shows a corresponding circuit board socket for a printed circuit board (FIG. 7a) and the signal assignment of the relay contacts (FIG. 7b) of a four-pole embodiment of a relay according to the invention.

FIG. 8 shows an embodiment of an electronic relay 100 according to the invention with a printed circuit board 134, which is mounted vertically on a base part 136. In this case, the printed circuit board 134 supports all the circuit components of the electronic relay, specifically the voltage supply circuit 102, the wireless communications interface 106 and the processor 110. On its lower edge, the printed circuit board 134 has soldering points, via which it is electrically connected to the plug-in contacts. For increasing mechanical stability, the printed circuit board 134 has two soldering points 138 on its lateral edges, via which it is connected to the bow-type ends 140 of two of the plug-in contacts.

FIG. 9 shows the electronic relay in the embodiment according to FIG. 8, once it has been plugged into a socket 144 located on a printed circuit board 142.

FIG. 10 shows an embodiment of an electronic system 146 according to the invention, which is implemented, for example, with the help of two printed circuit boards 142.1 and 142.2.

The electronic relays 100.1 and 100.2, each of which corresponds to the embodiment of FIG. 1, are plugged into the printed circuit board 142.1, for example. The electronic relay 100.1 forms a first node (“node 1”) and the electronic relay 100.2 forms a second node (“node 2”) of a ZigBee wireless communications network.

The control plug-in contact 15 of the electronic relay 100.1 can be connected to a switch, for example. One or more of the signal input plug-in contacts W, X, Y and/or Z can be connected to a sensor, for example, to a temperature sensor, in order to receive corresponding sensor signals. Moreover, plug-in contacts, i.e., the output plug-in contacts 87 and 87a, of the electronic relay 100.1 can be connected to actuators, for example, relays.

This description applies similarly to the additional electronic relays 100.2, 100.3 and 100.4 of the electronic system 146.

The printed circuit board 142.2 of the electronic system 146 supports, for example, the electronic relays 100.3, 100.4 and other wired and/or ZigBee subscribers 148 and various additional ZigBee modules, which belong to the wireless communications network 150, and with which additional nodes are formed.

For example, the electronic relay 100.3 forms a node 3 (“node 3”) of the wireless communications network 150, and the electronic relay 100.4 forms the so-called ZigBee coordinator. The electronic relays 100.3 and 100.4 have an expanded range of functions in relation to the electronic relays 100.1 and 100.2 and correspond to the embodiment according to FIG. 4.

The electronic relays 100.1 and 100.2 can be so-called ZigBee “end devices” (or “reduced function devices”—RFD) and the electronic relay 100.3 can be a ZigBee router (i.e. a so-called “full function device”—FFD) and the electronic relay 100.4 can be a “coordinator” of the ZigBee wireless communications network 150.

Based upon ZigBee wireless communications, each of the network nodes of the wireless communications network 150 can exchange data signals with each of the other nodes, even beyond the limits of the respective printed circuit boards.

Printed circuit board 142.2 can represent a module, for example, which can also be operated without the printed circuit board 142.1. If additional customer-specific or application-specific functionalities are required, for example, the electronic system 146 can be expanded by the printed circuit board 142.1, without requiring hardware changes to the partial system, represented by the printed circuit board 142.2, of the electronic system 146. For example, the electronic relays 100.1 and 100.2 can be incorporated into the wireless communications network 150 by so-called ad-hoc association.

However, the electronic system 146 can also be implemented as a single printed circuit board 142.

With the electronic device 100.4, i.e. the ZigBee coordinator, for example, the program instructions 112 of a single, of multiple, or of all the electronic relays 100 of the electronic system 146 can be updated, in that updated program instructions are transferred via the ZigBee wireless communications network 150 to the relevant electronic relay.

FIG. 11 shows an embodiment of an electronic system 146, after the electronic relay 100.3 has failed or has been removed from the electronic system 146, for example. Communication via the ZigBee wireless communications network 150 with this electronic relay 100.3 then is temporarily no longer possible.

The coordinator of the ZigBee wireless communications network 150 may also fail, however, the network 150 will continue to be available. Once the network 150 has been set up for the first time by the coordinator, the coordinator is no longer absolutely necessary for the actual network 150, except for those functions specifically assigned to it. Thereafter, the other subscribers will set up the network 150 independently, even after a restarting of the entire system and even without the coordinator.

In this case, for example, the electronic relay 100.4, i.e. the coordinator, can identify another electronic relay 100.x of the ZigBee wireless communications network 150 as a replacement for the failed electronic relay 100.3, so that the electronic system 146 can continue to be operated with the same or essentially the same range of functions. Following a restart of the electronic relay 100.3, for example, by the watchdog (cf. building block 132 of FIG. 4), for example, or a replacement of the electronic relay 100.3, said relay will be reconnected by the electronic relay 100.4, i.e. the coordinator, to the ZigBee wireless communications network 150, and can perform its original function. Thus, with the ZigBee wireless communications network 150, redundancy for the electronic system 146 can be created for the purpose of increasing its safety against failure.

For example, the electronic relay 100.3 according to the embodiment of FIG. 4 can be provided with a watchdog, which signals the occurrence of an error status in relation to the electronic relay 100.4, so that this will temporarily replace the failed electronic relay 100.3 with another electronic relay 100.x of the ZigBee wireless communications network 150.

FIG. 12 shows a flow chart of one embodiment of a method according to the invention. In step 200, an electronic relay of the wireless communications network, for example, electronic relay 100.1, receives a data signal 118 (cf. FIGS. 1 and 10) from the electronic relay 100.4. In the embodiment considered here, the data signal 118 contains the threshold values S1 and S2, which are stored by the electronic relay 100.1.

In step 202, the electronic relay 100.1 then receives at least one measured value M1, for example, in the form of the data signal 122, which carries a measured value M1. The data signal 122 with the measured value M1 (sensor signal) is received by the electronic relay 100.3 from one of the sensors connected to the electronic relay 100.3 for example transmitted via a wired data bus at one of the signal input plug-ins W, X, Y, or Z of the electronic relay 100.1. Alternatively this sensor can be directly connected to one of the signal input plug-ins W, X, Y, or Z of the electronic relay 100.1.

Alternatively or additionally, the electronic relay 100.1 can receive a further data signal 152 via one of its signal intake plug-in contacts W, X, Y or Z.

In step 204, the electronic relay 100.1 carries out a check to determine whether the measured value M1 lies below the threshold value S1. If this is the case, in step 206 the semiconductor switches of relay 100.1 will be actuated for switching. If the opposite is the case, a check will be carried out in step 208 to determine whether the measured value M1 lies below the threshold value S2. If this is the case, the electronic relay 100.1 will generate in step 210 a data signal 124, which here is embodied as a switching signal, for the relay 100.2, and will transmit this switching signal in step 212 via the wireless communications network 150 to the electronic relay 100.2.

If, in contrast, the measured value M1 is greater than or equal to the threshold value S2, the electronic relay 100.1 will generate a data signal 124 for the electronic relay 100.3 (step 214) and will transmit this in step 216. The data signal 124 can be embodied as a switching signal, for example, for actuating the electronic relay 100.3 for switching, and/or can contain information that is to be further processed by the electronic relay 100.3, for example, in order to initiate further actions.

The entire logic and processing/handling of the inputs/outputs can also be implemented in the coordinator or in one or more other subscribers to the ZigBee wireless communications network 150 having corresponding performance capacity. These will in turn receive the necessary information (signal, status, measured values, etc.) from the nodes either automatically or upon request.

An electronic relay of the ZigBee wireless communications network 150 can be embodied such that it can be controlled entirely via the ZigBee wireless communications network 150, i.e. actuation occurs only via the wireless communications interface 106, and not via the control plug-in contact 15. In this embodiment, the control plug-in contact 15 can be dispensed with.

### LIST OF REFERENCE SIGNS

15 Control plug-in contact
30 Input plug-in contact
31 Grounding plug-in contact
87 Output plug-in contact
87a Output plug-in contact
100 Electronic relay
102 Voltage supply circuit
104 Electronic component
106 Wireless communications interface
108 Antenna
110 Processor
112 Program instructions
114 Outputs
116 Semiconductor switch
118 Data signal
120 First switching signal
122 Second switching signal
124 Data signal
126 Data signal
128 Microcontroller
130 Serial interface
132 Building block
134 Printed circuit board
136 Base part
138 Soldering point
140 Ends
142 Printed circuit board
144 Socket
146 Electronic system
148 Subscriber
150 Wireless communications network
152 Data signal
154 Wireless remote controller
156 Operating field
158 Program module
160 Program module
162 Sensors
164 Reed switch

What is claimed is:

1. An electronic relay comprising
an input plug-in contact and at least one output plug-in contact for a current to be switched,
an electronic component for processing data and for actuating a semiconductor switch for switching the current,
a wireless communications interface for connecting with a wireless communications network, wherein the wireless communications interface is configured for receiving a first switching signal,
a control plug-in contact for receiving a second switching signal,
at least one signal input plug-in for receiving at least a first data signal,
wherein the electronic component is configured such that, in response to the reception of the first or second switching signal, the semiconductor switch is actuated for switching the current, and such that data processing occurs when the first data signal received via the at least one signal input plug-in is processed and, depending on a result of the data processing of the first data signal, the semiconductor switch is actuated for switching the current.

2. The electronic relay according to claim 1, wherein the first data signal is a measured value, wherein the measured value is processed by checking whether the measured value satisfies a predefined criterion for actuating the semiconductor switch for switching the current when the predefined criterion is satisfied by the measured value.

3. The electronic relay according to claim 1, wherein the electronic component is configured such that a second data signal is generated, wherein the wireless communications interface is configured for transmitting the second data signal.

4. The electronic relay according to claim 3, wherein the second data signal is transmitted as a unicast, multicast or broadcast signal.

5. The electronic relay according to claim 1, wherein as a result of the data processing, a fulfillment of an emergency shut-off condition is detected, and, based upon the detection of the fulfillment of an emergency shut-off condition, a second data signal is generated, which contains a shut-off command, wherein the second data signal is transmitted as a broadcast signal.

6. The electronic relay according to claim 1, wherein the wireless communication interface is configured for receiving a third data signal, wherein the electronic component is configured such that the third data signal is included in the processing of the first data signal and/or in the generation of the second data signal.

7. The electronic relay according to claim 6, wherein the third data signal is a sensor signal.

8. The electronic relay according to claim 1, further comprising a microcontroller for implementing at least a part of the data processing by executing program instructions.

9. The electronic relay according to claim 1, further comprising a bus interface for connection to an internal and/or external wired data bus.

10. The electronic relay according to claim 1, further comprising a self-diagnosis component for detecting an error status of the electronic component, wherein the self-diagnosis component is configured for generating an error status signal, and the wireless communications interface is configured for transmitting the error status signal.

11. The electronic relay according to claim 1, wherein the wireless communications interface is selected from one or more of the following a WLAN interface, a personal area network (WPAN) interface, a Bluetooth interface, an ultra-wideband (UWB) interface, a Z-wave interface, an IEEE 802.15.4 interface, a Vehicular Ad-Hoc Network (VANET)-interface and a ZigBee-interface.

12. The electronic relay according to claim 1, wherein the wireless communications interface is configured for performing the function of one or more of the following: a coordinator, router and end device in the wireless communications network.

13. The electronic relay according to claim 1, further comprising a registration component, said registration component capable of registering the electronic relay in the wireless communications network, wherein the registration component is configured for executing a registration protocol when the electronic relay is in a registration mode, and further comprising a switching component, said witching component capable of switching the electronic relay to the registration mode, wherein the switching component contains at least one contactless sensor, which is configured for sensing an actuation operation, with which the switching is initiated.

14. The electronic relay according to claim 13, wherein the registration protocol is a pairing protocol.

15. The electronic relay according to claim 13, wherein the contactless sensor comprises one or more sensors for detecting a magnetic field.

16. The electronic relay according to claim 15, wherein the sensors for detecting a magnetic field are arranged for generating a characteristic switching sequence when a magnet is moved past them as a result of the actuation operation, wherein the switching component is configured for switching to the registration mode for detecting the characteristic switching sequence, in order to switch to the registration mode based upon the detection of the characteristic switching sequence.

17. An electronic system comprising a printed circuit board, into which one or more electronic relays according to claim 1 are plugged.

18. The electronic system according to claim 17, further comprising at least one additional component that is separate from the printed circuit board, wherein the additional component has a wireless communications interface for connection to a wireless communications network.

19. The electronic system according to claim 18, wherein the additional component is one or more of the following: at least one additional electronic relay according to claim 1, a signal generator, a coordinator and an assembled printed circuit board.

20. The electronic system according to claim 17, wherein a coordinator is configured for transmitting an update of program instructions via the wireless communications network to the one or more electronic relays.

21. The electronic system according to claim 17, further comprising a portable wireless remote controller, wherein each of the one or more electronic relays has
an input plug-in contact and at least one output plug-in contact for a current to be switched,
an electronic component for processing data and for actuating a semiconductor switch for switching the current,
a wireless communications interface for connection to the wireless communications network, wherein the wireless communications interface is configured at least for receiving a first switching signal,
a control plug-in contact for receiving a second switching signal,
wherein the electronic component is configured such that based upon reception of the first or second switching signal, the semiconductor switch is actuated for switching the current, and such that data processing occurs when a first data signal received via the control plug-in contact is processed and, based upon a result of the data processing of the first data signal, the semiconductor switch is actuated for switching the current, and/or the first data signal is forwarded to the respectively other relay via the wireless communications network,
wherein the wireless remote controller is configured for transmitting the first switching signal via the wireless communications network.

22. A method for switching a power current with the help of an electronic system according to claim 17, comprising the following steps:
receiving a first switching signal via a wireless communications interface of a first electronic relay, whereupon a semiconductor switch of the first electronic relay is actuated for switching the power current,
receiving a second switching signal via a control plug-in contact of the first electronic relay, whereupon the power current is actuated by actuating the semiconductor switch of the first electronic relay,
receiving a first data signal via at least one signal input plug-in contact of the first electronic relay,
processing the first data signal by the first electronic relay, in order to actuate the semiconductor switch of the first electronic relay for switching the power current based upon the result of the processing of the first data signal, and/or to generate a second data signal in order to transmit the second data signal via the wireless communications interface of the first electronic relay to a second electronic relay, wherein the second data signal received from the second electronic relay is then further processed and/or further transmitted.

23. The method according to claim 22, wherein the power current is pulse-width modulated by the first and/or the second switching signal and/or the first data signal, in that the semiconductor switch is repeatedly actuated for implementing the pulse-width modulation, in order to adjust a current intensity of the power current.
